(19) United States
(12) Patent Application Publication
(10) Pub. No.: US 2013/0037088 A1
(43) Pub. Date: Feb. 14, 2013

(54) FOUNDATION SYSTEM FOR SOLAR PANELS HAVING PREASSEMBLED FITTINGS

(71) Applicant: Guenther Thurner, Strasskirchen (DE)

(72) Inventor: Guenther Thurner, Strasskirchen (DE)

(21) Appl. No.: 13/574,554

(22) PCT Filed: Jan. 18, 2011
(86) PCT No.: PCT/EP2011/050607

§ 371 Date: Oct. 12, 2012

(30) Foreign Application Priority Data
Jan. 20, 2010 (DE) 20 2010 001 186.8

(51) Int. Cl. H01L 31/048

(52) U.S. Cl. 136/251

(57) ABSTRACT

A foundation system for supporting solar panels provides longitudinal beams thereof that are pivotally supported on the transverse beams about axes running substantially coaxially to the longitudinal axis of the transverse beams or substantially horizontally, and fittings that are preassembled for fastening the longitudinal beams to the transverse beams, in which the fittings have pairs of clamping claws having members on a longitudinal beam side for clamping to the longitudinal beams in a fixed location, and on a transverse beam side for pivotally clamping to the transverse beams in a fixed location, and tie rods arranged between the longitudinal and transverse beam side members so that the clamping claws can be clamped against each other and against the longitudinal beams and the transverse beams.

### BACKGROUND OF THE INVENTION

It is known, in order to obtain solar power, to arrange a multiplicity of solar panels, in particular, for example, photovoltaic panels, in a sheetlike manner next to one another in one or else in a plurality of long rows next to one another and/or also above one another. In order to ensure optimum solar irradiation, the panels, or the area formed by the panels, need(s) to be aligned with respect to the sun in such a manner that as favorable a light incidence as possible is ensured over as large a portion of the day as possible. The panels or the rows of panels (unless omitted for reasons of economy, are—as is likewise known—provided to track the sun over the course of a day or even over the course of a year) and are therefore fixedly installed in as favorable as possible an inclination with respect to the sun.

The angle of inclination (with respect to the horizontal) is between 20 degrees and 30 degrees—depending on the geographical position of the system. In central European latitudes, an angle of 25-30 degrees is preferably provided.

If the surface on which the panels are intended to be installed already predetermines a corresponding inclination, as is frequently the case, for example in roofs, the panels are fitted on the predetermined surface in a row next to one another, for example on longitudinal members (purlins), and optionally also in a plurality of rows above one another.

If the predetermined surface does not predetermine any suitable inclination with respect to the sun, for example even, as frequently happens upon installation on the ground, the panels or the panel surfaces have to be erected in such a manner that they adopt the desired inclination with respect to the sun.

This is undertaken in practice by the longitudinal members (purlins), on which the one or more rows of panels arranged in a sheetlike manner next to one another are held, being mounted on a plurality of crossmembers (rafters) corresponding to the length of the one or more rows of panels, said crossmembers, for their part, being mounted on the underlying surface on in each case a shorter and a longer post in such a manner that said crossmembers and, together therewith, the purlins mounted thereon and the rows of panels mounted on the latter are inclined with the surface thereof at the desired angle with respect to the sun (for example in the south direction in the Northern Hemisphere). In this manner, for example, large arrays are equipped with such single or multi-row panel groups, a plurality of which are then in turn erected in a staggered manner one behind another (for example in the north-south direction in the Northern Hemisphere).

It goes without saying that the longitudinal members have to be fixed on the crossmembers. If the system is erected on the ground, this does not involve any particular problems. In principle, a simple screw connection, for example consisting of a screw bolt or nut, should suffice. However, in actual fact, even upon installation on the ground, a series of factors come into play which make the installation difficult or may considerably delay the latter, which is not acceptable for reasons of economy.

This includes, for example, inaccuracies in the foundation work which may result in stresses during installation, which have to be compensated for, and which, for example, may make it necessary for the installation to be carried out by a number of assistants. Further factors to be taken into consideration include the problems of installation in winter (with thick gloves), which make handling of fittings difficult because, for example, said fittings may drop down (into the snow) and become lost. These and other considerations make it appear appropriate, for the installation of the crossmembers on the longitudinal members, and even in the simplest case of installation on flat terrain, to provide entirely or partially preassembled or preassemblable fittings which, for example, also make it possible to provide the installation with just a few actions by a single person.

For reasons of economy, in order not to have to stock a plurality of types of fittings, where possible, with said fittings, it is intended at the same time to overcome the additional problems which occur upon installation of such rows of solar panels in a terrain with an incline in the east-west direction.

In such a terrain, the system as a whole has to follow the incline because otherwise the posts would become longer and longer, and therefore ever more expensive and ultimately ever more unstable. If, however, the system follows the incline, i.e., the crossmembers located next to one another come to stand lower and lower as the terrain drops away, or, conversely, stand higher and higher as the terrain rises, the longitudinal members also have to be adapted thereto, i.e., they have to follow the gradient.

Since the crossmembers in this case too are expediently erected on vertical posts, and the crossmembers generally have a rectangular cross section, tilting arises between the longitudinal members and the crossmembers, said tilting—unless special measures are taken—making the fastening difficult or even having an adverse effect on the system stability.

This defect could indeed be compensated for by the crossmember and longitudinal member profiles being matched to one another in such a manner that they bear in a sheetlike manner against one another even in an inclined position of the longitudinal members. This admittedly presupposes special constructions of the member profiles, which rule out the use of standard profiles and make the foundation systems correspondingly more expensive. This also makes it appear appropriate to solve the problems of this connection of the longitudinal and crossmembers structurally in a fitting to be provided there.

Added to this is the fact that the easy construction of large solar installations very much depends on the longitudinal members (purlins) running rectilinearly in plan view and the plurality of longitudinal members belonging to a row of panels running in absolute parallelism. Otherwise, easy installation of the solar panels to be mounted therebetween is made more difficult or impossible, or even damage occurs to the panels. In order to ensure such an identical direction of the longitudinal members, the crossmembers, for their part, are oriented precisely with one another such that they are aligned with one another. It is thus ensured on flat terrain that the longitudinal members always meet the subsequent crossmember, and their bearing points provided thereon, in the same position (alignment).

If, however, the longitudinal members rest on the inclined crossmembers without particular precautions and then follow a terrain incline, i.e., for example, pivot downward or upward, they do not pivot vertically but rather radially about the inclined longitudinal axis of the crossmember. That is to say, they migrate in proportion to the pivoting thereof from the lateral alignment with the next crossmember or crossmembers.

This may be able to be compensated for to a certain degree, i.e. in the case of a small terrain drop or rise, by corresponding deformation of the longitudinal members. However, this is subject to relatively narrow limits because each deformation of the longitudinal members runs the risk that the panels will no longer be reliably grasped and held or may even be under such stress that they are damaged or destroyed. In any case, however, under stresses of this type, the rectilinear alignment of the panel arrays and therefore at least the appearance and, consequently, the acceptance of the product (the system) suffers.

It may therefore be appropriate, also for this problem, to provide a correction (of the pivot axis of the longitudinal members) with a (partially) preassembled or (partially) preassemblable fitting between the crossmember and longitudinal member.

### SUMMARY OF THE INVENTION

Accordingly, it is an object of the invention to propose a foundation system for solar panels and in particular components or fittings with which, or with the aid of which, the simple, cost-effective and stable installation of the longitudinal members in the desired alignment can be ensured on any terrain, in particular even on difficult terrain, in particular with an incline in the east-west direction.

This object is variously achieved by a foundation system, a preassembled fitting, a crossmember (rafter) with preassembled fittings and a crossmember with a pivot bearing, in accordance with the present invention as described hereinbelow.

The foundation system according to the invention for supporting solar panels, that are in particular photovoltaic panels, arranged in a sheetlike manner next to one another at an inclination with respect to the sun consists of two or more longitudinal members arranged next to one another for the sheetlike holding of one or more rows of solar panels arranged next to one another. Depending on the length of the rows and, accordingly, the length of the longitudinal members holding said rows, the longitudinal members rest on a plurality of crossmembers which are aligned with one another and are inclined with respect to the sun. The crossmembers rest on supports and are erected by means of said supports in the north-south direction inclined at the desired angle with respect to the sun such that the longitudinal members mounted thereon together with the panels or panel surfaces held by said longitudinal members are directed at the same inclination with respect to the sun.

To the extent that this involves installation on the ground, or at most on slopes with a north-south incline, precise alignment of the crossmembers with respect to one another with the aid of the posts holding the crossmembers ensures a progression of the longitudinal members mounted thereon, the progression being rectilinear in plan view, and the precise parallel alignment of a plurality of longitudinal members of a panel surface and therefore at the same time easy, stress-free installation of the longitudinal members and of the panels, and a harmonious overall appearance of the system.

For simple fastening of the longitudinal members to the crossmembers, entirely or partially preassembled or preassemblable fittings are provided, which fittings do not first have to be assembled on the terrain, for example in rain and snow, and can be assembled with few maneuvers and thus, for example, enable installation by a single person.

The fittings enclose an axis which runs in the longitudinal direction of the crossmembers and ensures reliable mounting of the longitudinal members on the crossmembers even if—for example on uneven terrain—tilting occurs between the intersecting longitudinal and crossmembers.

The axis or the axes of the plurality of fittings required for the construction of a system may be directed substantially coaxially with respect to the crossmembers. In order to avoid difficulties which arise from said alignment of the axes, the latter may also run substantially horizontally.

It has namely been shown that the longitudinal members crossing the inclined crossmembers, if said longitudinal members are pivoted about axes coaxial with respect to the crossmembers, in order to compensate for an incline downward or upward, do not move in a vertical plane, and therefore in alignment with the aligned next crossmember or the coupling point (bearing point) provided there for the longitudinal member, but rather pivot radially with respect to the crossmember as an (inclined) pivot axis. They are therefore deflected laterally away from the designated coupling point. This misalignment can be avoided by a horizontal or approximately horizontal alignment of the axes.

So that at most little, if any, preparation work is required at the building site, in particular so that a multiplicity of individual parts do not have to be assembled, the fittings are designed to be entirely or partially preassembled or preassemblable.

In their simplest form, the fittings consist of a pair of clamping claws with longitudinal-member-side means for clamping fixing of said clamping claws to the longitudinal members, crossmember-side means for the pivotable and clamping fixing of said clamping claws to the crossmembers, and tie rods which are arranged between the longitudinal-member-side and the crossmember-side means and by means of which the clamping claws can be braced in relation to one another and against the longitudinal members and the crossmembers for the fixing thereof.

Owing to the fact that at least two tie rods are used, the preassembled fitting, even in the preassembly state, obtains such stability, in particular as far as tilting is concerned, that it does not obstruct the alignment of the system components, which are initially still connected loosely to one another for this purpose, in particular the displacement of the longitudinal members and the crossmembers in relation to one another.

In order to ensure the pivotable mounting of the longitudinal members on the crossmembers, the crossmembers can have crossmember-side parts of pivot bearings, in which the crossmember-side means of the clamping claws can engage with the pivotable mounting and clamping fixing thereof, with the pivot axis being formed.

The crossmember-side parts of the pivot bearings may be designed as bearing sleeves which are then mounted on the crossmember, for example by means of a web. However, they are preferably designed as profiles which are bent in a U-shaped manner and are fixed at the free ends thereof to the crossmember. This has the advantage of a very simple construction from a single piece of appropriately shaped flat steel which, in addition, unlike a web which would have to be attached centrally on the crossmember profile, would be welded on both sides at the free ends thereof onto the stiffer profile longitudinal sides of the crossmembers, thus resulting in significantly improved strength and durability of the structure.

In order to ensure a precise seat of the clamping claws on the crossmember-side part of the pivot bearing (providing the bearing sleeve and/the U profile), the seat thereof can be correspondingly designed, i.e. for example, in the manner of a truncated cone or a ball.

The construction according to the invention is particularly advantageous if the at least two tie rods are positioned between the longitudinal-member-side means for the clamping fixing of the clamping claw pairs to the longitudinal members and the crossmember-side means for the pivotable and clamping fixing of the clamping claw pairs to the crossmembers and/or the pivot bearing in such a manner that the longitudinal members can slide on the tie rods when being aligned. This is because the longitudinal member is then very readily longitudinally displaceable if this is required for the alignment thereof. In particular, the longitudinal member then stabilizes the preassembled fitting in such a manner that tilting, which would wedge the longitudinal member and obstruct the alignment thereof by displacement, is avoided.

In order to further facilitate the construction of the system, spike extensions are provided on the upper side of the pivot bearings and of the crossmember-side parts of the pivot bearings, said spike extensions, for guiding the longitudinal members, which still rest loosely, upon the longitudinal alignment thereof, engaging in longitudinal slots on the longitudinal members.

In order to facilitate the construction of the foundation systems even further, a holding device which acts as an installation aid and holds the fittings in a position ready for installation can be provided on the preassemblable or preassembled fittings.

This installation aid may be designed to be elastic so as to be elastically displaceable counter to the resetting forces thereof over the course of the installation. In the case of the elastic design, this may at the same time have the advantage that, in the event of disassembly, the holding device brings the fitting automatically back into the (disassembly) installation position.

### BRIEF DESCRIPTION OF THE DRAWINGS

The invention is explained in more detail below with reference to the drawings, in which:

FIG. 1 shows a foundation system, which is reproduced in a perspective view, for the mounting, at an inclination with respect to the sun, of solar panels arranged in a sheetlike manner next to one another.

FIG. 2 shows the foundation system according to FIG. 1 in side view.

FIG. 3 shows a fitting according to the invention with a crossmember-side pivot bearing, which is designed as a bearing sleeve, in a perspective illustration.

FIG. 4 shows the fitting according to FIG. 3 in section.

FIG. 5 shows the fitting according to FIG. 3 in side view.

FIG. 6 shows the fitting according to FIG. 3 in axial plan view.

FIG. 7 shows a fitting according to the invention with a crossmember-side part of the pivot bearing, which part is designed as a U-shaped profile, in a perspective illustration.

FIG. 8 shows the fitting according to FIG. 7 in axial plan view.

FIG. 9 shows the fitting according to FIG. 7 in plan view.

FIG. 10 shows the fitting according to FIG. 7 in side view.

### DETAILED DESCRIPTION OF THE INVENTION

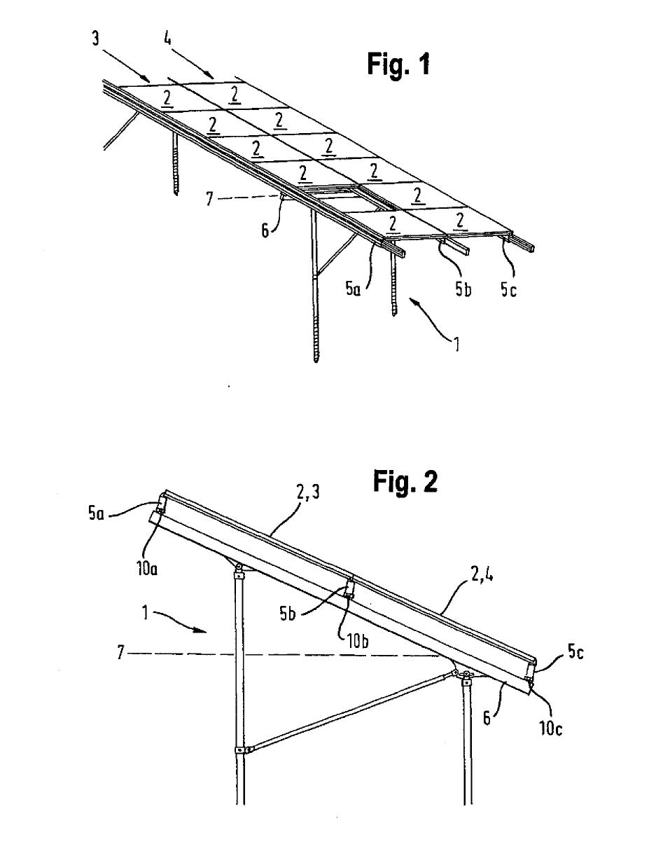

FIG. 1 shows, in a perspective view, the foundation system 1 for the mounting, inclined with respect to the sun, of solar panels 2 which are arranged in a sheetlike manner next to one another in one or more rows 3, 4, are held by longitudinal members 5a-c and are mounted by means of the longitudinal members on crossmembers 6 which, for their part, are held by vertical posts for mounting on the underlying surface.

FIG. 2 shows the foundation system 1 according to FIG. 1 in side view. Said system consists of two rows 3, 4 of solar panels 2 which are held by longitudinal members 5a-c which rest on crossmembers 6 which are inclined in the longitudinal direction 7 thereof with respect to the sun and, for their part, are supported by the vertical posts.

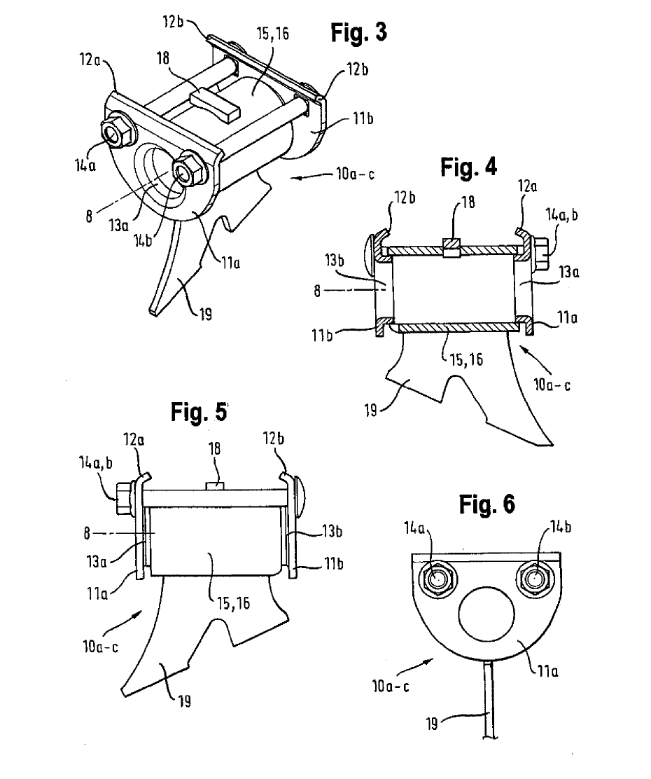

FIGS. 3, 4 and 5 provide respective perspective, sectional and side views of a fitting 10 according to the invention with a pair of clamping claws 11a, b with means 12a, b for the longitudinal-member-side fixing, and means 13a, b for the crossmember-side fixing, of the claws 11a, b, and two tie rods 14a, b for bracing the clamping claws 11a, b in relation to each other and to the longitudinal members and crossmembers 5, 6 of FIGS. 1-2. Also shown is a crossmember-side part of a pivot bearing 15, which part is designed as a bearing sleeve 16 and is fixable, for example weldable, on a crossmember 6 of FIGS. 1-2 by means of a web 19. The clamping claws 11a, b engage by means of the crossmember-side means 13a, b thereof in the bearing sleeve 16, with a pivot axis 8 being formed. Also shown is a spike extension 18 which, for guiding and aligning a longitudinal member 5 (not shown), rested loosely on the fitting 10 and on the tie rods 14a, b, can engage in a longitudinal slot provided on said longitudinal member.

FIG. 6 shows the fitting 10 according to FIG. 3 in axial plan view with a clamping claw 11 and tie rods 14a, b.

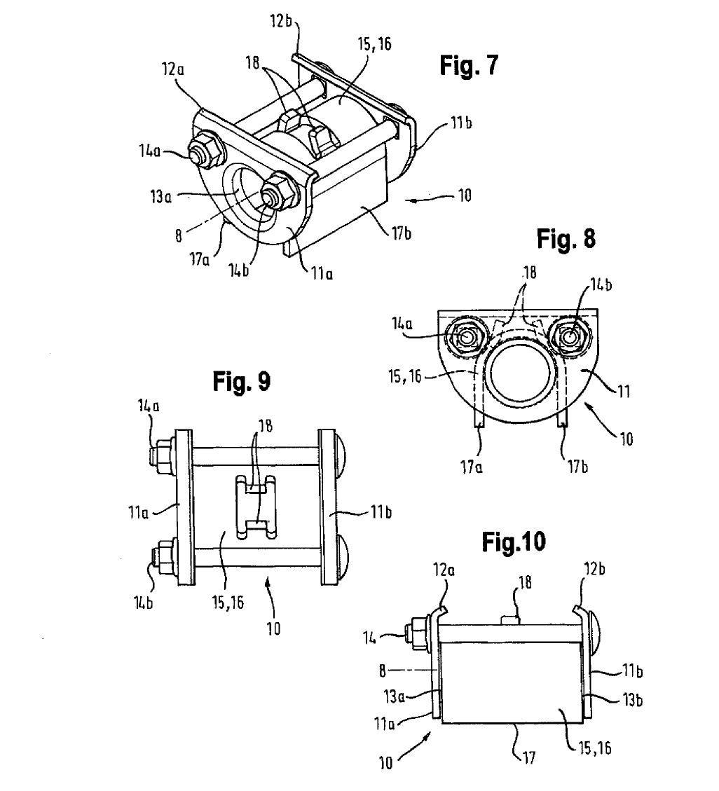

FIGS. 7 and 10 provide respective perspective and side views of another fitting 10 according to the invention with a pair of clamping claws 11a, b with means 12a, b for the longitudinal-member-side fixing, and means 13a, b for the crossmember-side fixing, of the claws 11a, b, and two tie rods 14a, b for bracing the clamping claws 11a, b in relation to each other and to the longitudinal and crossmembers 5, 6 of FIGS. 1-2. Also shown is a crossmember-side part of a pivot bearing 15, which part is designed as a U profile 16 and is fixable, for example weldable, at the free ends 17a, b thereof to a crossmember 6 of FIGS. 1-2. The clamping claws 11a, b engage by means of the crossmember-side means 13a, b thereof in the U profile 16, with a pivot axis 8 being formed. Also shown is a spike extension 18 which, for guiding and aligning a longitudinal member 5 of FIGS. 1-2, which is placed loosely onto the fitting 10 and onto the tie rods 14a, b, can engage in a longitudinal slot provided on said longitudinal member.

FIG. 8 shows the fitting 10 according to FIG. 7 in an axial plan view with a clamping claw 11, tie rods 14a, b, and a crossmember-side part of the pivot bearing 15, which part is designed as a U profile 16 and has free ends 17a, b which are fixable, for example weldable, to a crossmember 6 of FIGS. 1-2.

FIG. 9 shows the fitting 10 according to FIG. 7 in plan view with clamping claws 11a, b, tie rods 14a, b, a crossmember-side part 16 of the pivot bearing 15 as a U profile 16, and a spike extension 18 for guiding a longitudinal member 5 of FIGS. 1-2.

FIG. 10 shows the fitting 10 according to FIG. 7 in side view with clamping claws 11a, b with means 12a, b for the longitudinal-member-side fixing, and means 13a, b for the crossmember-side fixing, of the claws 11a, b, and one of the tie rods 14a, b for bracing the clamping claws 11a, b in relation to each other and to the longitudinal and crossmembers 5, 6 (not shown). Also shown is a crossmember-side part 16 of the pivot bearing 15, which part is designed as a U profile 16 and is fixable, for example weldable, by means of the free ends 17 thereof to a crossmember 6 (not illustrated).

The clamping claws 11a, b engage by means of the crossmember-side means 13a, b thereof in the U profile 16, with a pivot axis 8 being formed. Also shown is the spike extension 18 which, for guiding and aligning a longitudinal member 5 of FIGS. 1-2, which is placed loosely onto the fitting 10 and onto the tie rods 14a, b, can engage in a longitudinal slot provided on said longitudinal member.

1. A foundation system for supporting solar panels which are arranged in a sheetlike manner next to one another and are held next to one another in one or more rows by longitudinal members which rest on a plurality of crossmembers, which are arranged next to one another and are inclined with respect to a horizontal, and comprising
the longitudinal members being mounted pivotably on the crossmembers about axes running substantially coaxially or substantially horizontally in the longitudinal direction of the crossmembers, which axes are formed on entirely or partially preassembled or preassemblable fittings for fastening the longitudinal members on the crossmembers, the fittings have having pairs of clamping claws,
longitudinal-member-side members for the clamping fixing of said clamping claws on the longitudinal members,
crossmember-side members for the pivotable and clamping fixing of said clamping claws on the crossmembers (6),
and tie rods which are arranged between the longitudinal-member-side members and the crossmember-side members so that the clamping claws can be braced in relation to one another and against the longitudinal members and the crossmembers.

2. The foundation system as claimed in claim 1, wherein the crossmembers have pivot bearings comprising crossmember-side members, in which the crossmember-side members of the clamping claws engage for the pivotable mounting and clamping fixing thereof relative to the longitudinal members and the crossmembers, about a pivot axis.

3. The foundation system as claimed in claims 1 or 2, wherein a respective crossmember-side member comprises a U-shape and is fixed at free ends thereof to a crossmember.

4. The foundation system as claimed in claim 3, wherein a seat of the clamping claws comprises a truncated cone or a ball shape.

5. The foundation system as claimed in claim 1, wherein the tie rods are positioned between the longitudinal-member-side members for the clamping fixing of the clamping claw pairs on the longitudinal members and the
crossmember-side members for the pivotable and clamping fixing of the clamping claw pairs on the crossmembers and/or the pivot bearing so that the longitudinal members are mountable in a slidable manner upon being aligned with the tie rods.

6. The foundation system as claimed in claim 5, wherein the crossmember-side members comprise spike extensions which engage in longitudinal slots on the longitudinal members for guiding the longitudinal members upon the longitudinal alignment thereof.

7. The foundation system as claimed in one claim 1, wherein the preassemblable or preassembled fittings are held in a position ready for installation by means of a holding device forming an installation aid.

8. The foundation system as claimed in claim 7, wherein the holding device is elastic so as to be elastically displaceable counter to resetting forces thereof during the course of the installation.

9.-11. (canceled)

12. A preassembled fitting in accordance with the foundation system of claim 1.

13. A crossmember and preassembled fitting in accordance with the foundation system of claim 1 in which the preassembled fitting is preassembled onto the crossmember.

14. A crossmember in accordance with the foundation system of claim 1 in which the crossmembers has a pivot bearing comprising crossmember-side-members, in which the cross-member-side members of the clamping claws engage for the pivotable mounting and clamping fitting thereof relative to the longitudinal members and the crossmembers.
